(19) United States
(12) Patent Application Publication
(10) Pub. No.: US 2026/0314064 A1
(43) Pub. Date: Oct. 8, 2026

(54) A TRANSISTOR DEVICE AND A METHOD OF OPERATING THEREOF

(71) Applicant: Search For The Next, LTD, Nottingham (GB)

(72) Inventors: David SUMMERLAND, Nottingham Nottinghamshire (GB); Roger LIGHT, Nottingham Nottinghamshire (GB); Luke KNIGHT, Nottingham Nottinghamshire (GB)

(21) Appl. No.: 18/708,105

(22) PCT Filed: Nov. 8, 2022
(86) PCT No.: PCT/GB2022/052820

§ 371 Date: May 7, 2024

(30) Foreign Application Priority Data
Nov. 8, 2021 (GB) 2118047.8
Dec. 9, 2021 (WO) PCT/GB2021/053234
May 23, 2022 (GB) 2207552.7
May 26, 2022 (GB) 2207801.8
Sep. 2, 2022 (GB) 2212821.9

(51) Int. Cl. H10D 84/90; H03K 19/20

(52) U.S. Cl. CPC H10D 84/901; H03K 19/20

(57) ABSTRACT

A bipolar transistor having a semiconductor structure that includes a channel of semiconductor type that is the same as the collector and emitter regions. The channel is significantly shallower than the base region with which it interfaces. The novel structure provides improved current gain. It also enables the device to operate, when on, selectively either with primarily unipolar conduction or primarily bipolar conduction by control of the voltage across the emitter and collector terminals.

### CROSS-REFERENCE TO RELATED APPLICATIONS

This application claims priority from and is related to the following prior application Patent Cooperation Treaty Application PCT/GB2022/052820, filed on Nov. 8, 2022, which claims priority from Great Britain Patent Application No. 2116047.8, filed on Nov. 8, 2021, and from Patent Cooperation Treaty Application PCT/GB2021/053234, filed on Dec. 9, 2021, and from Great Britain Patent Application No. 2207552.7, filed on May 23, 2022, and from Great Britain Patent Application No. 2207801.8, filed on May 26, 2022, and from Great Britain Patent Application No. 2212821.9, filed on Sep. 2, 2022. These prior applications, including the entirety of their written description and drawings, are collectively hereby incorporated by reference into the present application.

### BACKGROUND

The present invention relates to a novel transistor having, among other advantages, improved current gain characteristics over conventional lateral bipolar junction transistors (BJTs).

The semiconductor structure and doping configuration of a BJT is such that current between the emitter and collector (the controlled current) is a consequence of movement of both electron and electron hole charge carriers, referred to as bipolar conduction.

In contrast in a field effect transistor (FET) or Junction Field Effect transistor (JFET) current between the source and drain terminals (the controlled current) is primarily, if not solely, attributable to movement of either electrons or electron holes but not both, referred to as unipolar conduction or single-carrier-type operation.

U.S. Pat. No. 6,251,716B1, US200316704A1 and US2009206375 are examples of known JFET configurations current between the source and drain in these devices is primarily attributable to unipolar conduction

### BRIEF SUMMARY

According to a first aspect of the invention there is provided a circuit comprising:
a first transistor,
a base of the first transistor connected to a two state logic signal source;
the first transistor having:
   a collector region provided by a first region of semiconductor of a first type; a collector terminal associated with the collector region;
   an emitter region provided by a second region of semiconductor of the first type; an emitter terminal associated with the emitter region;
   a base region provided by a third region of semiconductor lying between and interfacing with both the collector region and emitter region; a base terminal associated with the base region;
wherein the base region includes:
   a sub-region of semiconductor of a second type; and
   a channel of semiconductor of the first type;
wherein the base terminal contacts the base region;
the sub-region interfaces with the channel to provide a first diode junction, and interfaces with both the emitter region and the collector region to form further diode junctions,
and the channel interfaces with and interconnects the collector region and the emitter region, the channel extending away from the first diode junction; and
in which the circuit is adapted to switchably operate, in response to a change in the two state logic signal between a first state and a second state;
the circuit comprises a load connected to an output of the first transistor, the circuit is adapted, when in operation, to provide a voltage V_{ce} across the collector and emitter to allow for a non-zero current through the collector terminal in both the first and second states; and
in the first state a first voltage V_{be1} is applied across the emitter and base of the first transistor to cause a first non-zero current I_{ce1} between the collector and emitter of the first transistor; and in the second state a second voltage V_{be2} of the same polarity to V_{be1} is applied across the emitter and base of the first transistor to cause a second, larger, non-zero current I_{ce2} between the collector and emitter of the first transistor, and
wherein |V_{ce|} is above a |threshold voltage|, and V_{be1} V_{be2} are selected so that in the first state I_{ce1} is predominantly attributable to unipolar conduction, and in the second state I_{ce2} is attributable to both unipolar and bipolar conduction.

The presence of the channel, in what is otherwise a substantially conventional BJT semiconductor structure, allows for unipolar conduction between the collector and emitter terminals. This provides the transistor with improved gain characteristics compared with BJT transistors with conventional structures. This is thought to be because the channel provides a conduction path between the emitter and collector regions without crossing a diode junction and which thus provides relatively low resistance.

The value of the threshold voltage for Vce depends on the thickness of the channel, and the length of the channel that extends between the emitter and collector regions and typically thus also the separational distance between the emitter region and collector region.

The presence of the channel, allows the transistor to switch ON, i.e. there is more than de minimis current through the collector terminal, at a |Vbe| value that is less than the forward bias voltage of the base emitter diode junction |(Vft)|. Whilst ON in this condition there is no current through the base terminal. The benefit of this feature will become apparent later.

Thus |Vbe1| is selected to be smaller than |Vft| to provide unipolar conduction, and |Vbe2| selected to be larger or the same as |Vft| to provide bipolar conduction.

Switching between a substantially exclusively unipolar mode of conduction and one which includes bipolar conduction has two benefits compared with operating in a unipolar conduction mode only: it minimises overshoot and enforces a known voltage limit.

If switching between two Vbe voltages in which current between the collector and emitter is exclusively attributable to unipolar conduction, it is possible for the voltage to overshoot when switching to the larger |Vbe| because an inrush charge to/from the base of the transistor. This introduces a delay as the overshot Vbe returns to the larger |Vbe| as the charge discharges/charges back from/to the base. This has the effect of limiting the maximum switching frequency because as switching frequency increases, the circuit will try to switch whilst the larger |Vbe| is still overshot. This problem is experienced with MOSFETs and JFETS where current between the gate and drain terminals is exclusively unipolar.

In contrast, when switching to a voltage Vbe where |Vbe|>|Vft|, such that current between the collector and emitter is attributable in part to bipolar conduction, the forward biased Base-Emitter junction causes rapid increase in base current as Vbe increases past Vft. This has the effect of clamping the larger |Vbe|, minimising overshoot and thus raising the maximum possible switching frequency.

Explained another way, if operating in exclusively unipolar mode, such as a JFET does, it would be possible to pull the base voltage (gate voltage for JFET) from rail to rail. However, in bipolar mode, there is a base current when |Vbe|>|Vft| which resists the pull to the rail and limits the Vbe voltage, meaning, at most, the voltage swing is from one rail to Vbe2. A smaller voltage swing allows for faster switching speeds.

Transistors and diodes on a wafer are never all identical, there will be subtle variations in gain, forward voltage etc, between adjacent devices. For example, when operating between nominal switching voltages of 0.4V-0.2V, one transistor may switch 0.35V-0.25V and another transistor between 0.45V-0.2V. This variation can be enough to prevent the circuit from working, for example, if an abnormally weak transistor drives an abnormally strong transistor.

By clamping one of the switching voltages for all transistors in the circuit, a larger tolerance is afforded to variations for the other switching voltage between transistors, reducing the likelihood of circuit misfunction.

Switching the transistor between two ON states in order to switch between one of two logic conditions at the output of the transistor, allows for operation with significantly reduced base capacitances, and thus a faster switching speed, compared with switching a comparably sized transistor operating at the same switching voltages between ON and OFF conditions.

The load on the output of the transistor functions to keep the transistor ON in both circuit logic states. The load may be provided, at least in part by a first diode between the output of the transistor and a reference voltage. This ensures a load is present even when the output of the transistor is connected to a next stage transistor that isn't drawing current from the transistor's output. In operation, the first diode may be reverse biased.

The circuit may include a second, reverse biased, diode connected between the base of the transistor and the reference voltage. The reversed biased second diode provides a pull up or down function (depending on whether the first transistor is a NPN or PNP transistor). Performing this function relies on there being a leakage current through the second diode. Favorably the circuit is operated such that the voltage across the second diode is below the second diode's breakdown voltage to provide current values amenable for fast logic switching.

As mentioned previously, a smaller switching voltage across Vft further increases the first transistor's switching speed. A further means to achieve smaller switching voltage is to include a third, favorably forward biased, diode in the circuit, arranged such that the signal source is connected to the base of the first transistor through the third diode. The third diode functions to dampen the size of the voltage swing of the signal source so as to reduce the voltage swing at the base terminal of the first transistor.

Through operating in one state such that there is bipolar conduction it is possible to limit the voltage swing, including overshoot if present, at the base terminal of the transistor to less than 0.6V. With introduction of the third diode, the voltage swing can be further reduced to 0.3V or less.

The first diode may be a Zener diode. The second diode may be a Zener diode. The third diode may be a Zener diode. The first diode may be a Schottky diode. The second diode may be a Schottky diode. The third diode may be a Schottky diode. The first diode may be a tunnel diode. The second diode may be a tunnel diode. The third diode may be a tunnel diode.

In one implementation, where the circuit is an integrated semiconductor circuit, the third diode maybe comprised from the third region of semiconductor that provides the base of the first transistor.

Where the third diode is a Schottky diode the third semiconductor region directly contacts a metal layer. Where the third diode is a Zener diode or a tunnel diode, it may be comprised from a further semiconductor region in direct contact with the third semiconductor region.

Either of these implementations provides a compact arrangement without the need for a separate integrated circuit component.

The circuit may comprise a second transistor, and wherein the output of the first transistor is connected to the base of the second transistor so as to control the second transistor. As such the first transistor, which may be referred to as the first stage transistor, drives the second transistor, which may be referred to as the second stage transistor. The first diode may be connected between the base of the second transistor and the reference voltage. As such the first diode may perform the dual functions of a load for the first transistor and the pull down/pull function for the second transistor (which is provided by the second diode for the first transistor). As such the first transistor may be, when in operation reversed biased. Further, the circuit is favorably operated such that the voltage across the first diode is below the first diode's breakdown voltage to provide current values amenable for fast logic switching.

The first and second transistors are favorably either both NPN transistors or both PNP transistors. This simplifies manufacture the circuit when implemented as an integrated semiconductor circuit.

The circuit may comprise a further third diode, and in which the output of the first transistor is connected to the base of the second transistor through the further third diode. Whereso, the first diode may be connected to the output of the first transistor through the further third diode. The further third diode acts to provide the same voltage swing suppression at the base of the second transistor as the third diode does for the first transistor. As such the third diode and further third diode may be substantially identical.

As described above the first transistor and second transistor (where present) each function as inverter logic gates.

The circuit may comprise one or more further two state logic signal sources, and one or more fourth diodes, each of the one or more further two state logic signal sources connected to the base of the first transistor through a different fourth diode of the one or more fourth diodes. This provides a simple means of implementing a NOR logic gate.

The circuit may comprise a fifth diode, the fifth diode arranged in parallel to the third diode between the signal source and the base of the first transistor; the third diode and the fifth diode being semiconductor diodes and of different types. One of the third and fifth diodes is Schottky diode. The other may be a Zener diode or a tunnel diode. This combination provides increased switching speed, maximum switching frequency and/or smaller device area compared with using a Zener or Schottky diode alone. Like the third diode, the fifth diode may be arranged, so when the circuit is in operation, it is forward biased.

A consequence of the manner in which the transistor(s) function is that as the value of Vbe changes above Vft, the proportion of Ice attributable to bipolar conduction and unipolar conduction changes and thus the current gain of the transistor changes; as the proportion of bipolar conduction increases the current gain drops.

A suitable depth (namely direction orthogonal to the first diode junction and direction of current flow through the channel) for the channel in the direction orthogonal to the first diode junction will depend on the values of Vce at which the transistor is designed to operate and/or the doping concentration of the channel.

For example, for a transistor adapted to operate within a nominal voltage range between 0V and |5V|, a channel depth below 0.25 μm and favorably 0.1 μm or less may be suitable.

Nevertheless, for a given operating voltage, the maximum depth of the channel permitted will be notably smaller than would exist for a JFET designed to operate at a comparable operating voltage.

In contrast, the depth of the sub-region extending in the opposite direction from the first diode junction may be equal or greater than five times that of the channel. In some embodiments the depth of the sub-region may be at least twenty time that of the channel.

The sub-region may comprise a first portion and a second portion, and wherein: the first portion has a higher net doping concentration than the second portion; the base terminal electrically connects to the second portion through the first portion; and in which the second portion interfaces with the channel to provide the first diode junction, and interfaces with both the emitter region and the collector region to form the further diode junctions. This ensures that a relatively high doped region can be used at the base contact to provide an ohmic contact, whilst a lower doped region interfaces with the channel, emitter and collector regions.

When operating in the second state Ice2 may be attributable primarily to unipolar conduction or bipolar conduction depending on the value of Vbe2. Ensuring predominately bipolar conduction is possible requires careful selection of the net doping concentrations of the emitter region, collector region and sub-region of the base, as well as the spacing between the emitter and collector regions, also known as the base width. The exact values will depend on variables such as the expected operating voltage ranges of Vce and Vbe and the semiconductor fabrication process size and material used. The approach used to select values for these variables is the same and common practice for designing a conventional BJT structure and so will be readily understood by the person skilled in the art.

The net doping concentration of the channel may be equal to or less than (e.g. between 0.1 and 1 times) the net doping concentration of sub-region. This ensures the depletion region at the first diode junction preferentially forms within the channel compared within the sub-region. For example, where the channel is comprised from P type semiconductor material and the sub region is comprised from an N type semiconductor material, the net doping concentration of P type dopant in the channel may be between 0.1 and 1 times the net concentration of N type dopant within the sub region.

To provide good conduction characteristics within the first part of the sub region, the first part of the sub-region may have a net doping concentration between 1e16 per cm3 and 5e17 per cm3 inclusive.

Good bipolar conduction characteristics also depend on a relatively small lateral separation between the collector and emitter regions, therefore the lateral separation between the collector and emitter regions may be less or equal to 1.5 microns.

Expressed as a fraction, the ratio of the channel depth: lateral separation between the collector and emitter regions may be ⅙ or less.

The emitter and/or collector regions may lie at least partly within the sub-region of the base.

The circuit may be a logic circuit. The circuit may implement a NOR gate.

### BRIEF DESCRIPTION OF THE DRAWINGS

The accompanying figures in which like reference numerals refer to identical or functionally similar elements throughout the separate views, and which together with the detailed description below are incorporated in and form part of the specification, serve to further illustrate various embodiments and to explain various principles and advantages all in accordance with the present disclosure, in which:

FIG. 1 is a schematic cross-section of a semiconductor structure implementing a transistor;

FIG. 2 is a chart illustrating how the operating characteristics of the transistor device of FIG. 1 varies with changes in Vbe and Vce;

FIG. 3A is a schematic cross-section of the device of FIG. 1 showing the transistor configured in an ON condition and in which conduction between the emitter and collector is primarily attributable to bipolar conduction;

FIG. 3B is a schematic cross-section of the device of FIG. 1 showing the transistor configured in an OFF condition;

FIG. 3C is a schematic cross-section of the device of FIG. 1 showing the transistor configured in an ON condition and in which conduction between the emitter and collector is primarily attributable to unipolar conduction;

FIG. 4A is a schematic cross-section of a transistor device similar to FIG. 1 but with a shorter spacing X, configured in an ON condition in which current between the emitter and collector is primarily attributable to unipolar conduction;

FIG. 4B is a schematic cross-section of the transistor device of FIG. 4A showing the transistor configured in an OFF condition;

FIG. 5A is a schematic cross-section of a variant semiconductor structure to implement a transistor device;

FIG. 5B is a plan view of the transistor implemented by the semiconductor structure illustrated in FIG. 5A;

FIGS. 6A to 6I are schematic representations illustrating process stages for the manufacture of the transistor device of FIGS. 5A and 5B;

FIG. 7 is a schematic of the transistor in a circuit functioning as an inverter logic gate;

FIG. 8A is a schematic of a first variant two stage buffer circuit;

FIG. 8B is a schematic of the first variant two stage buffer circuit of FIG. 8A illustrating example voltages at different points within the circuit and voltage drops across the diodes;

FIG. 9 is a schematic of a two-stage circuit in which each transistor is connected to two signal sources in parallel to implement logic NOR gates;

FIG. 10 is a schematic of a second variant two stage buffer circuit that provides faster switching speed over the first variant of FIGS. 8A and 8B;

FIG. 11 is a schematic of a variant two-stage circuit of FIG. 9 incorporating the features of FIG. 10 to provide faster switching speed;

FIG. 12A is a schematic cross-section of a further variant semiconductor structure to implement a transistor device with a Schottky diode;

FIG. 12B is a plan view of the transistor implemented by the semiconductor structure illustrated in FIG. 12A;

FIG. 13A is a schematic cross-section of another variant semiconductor structure to implement the transistor device;

FIG. 13B is a plan view of the transistor implemented by the semiconductor structure illustrated in FIG. 13A;

FIG. 14A is a schematic cross-section of an additional variant semiconductor structure to implement a transistor device;

FIG. 14B is a plan view of the transistor implemented by the semiconductor structure illustrated in FIG. 14A;

FIG. 15A is a plan view schematic of a variant semiconductor layer structure providing a vertical transistor;

FIG. 15B is a side cross-section schematic of the layer structure of FIG. 15A taken through vertical plane Q-Q; and

FIG. 16 is a is a side cross-section schematic of the layer structure used to implement a vertical transistor having connected to its base: two Schottky diodes and a Zener diode

### DETAILED DESCRIPTION

As required, detailed embodiments are disclosed herein; however, it is to be understood that the disclosed embodiments are merely examples and that the devices and methods described herein can be embodied in various forms. Therefore, specific structural and functional details disclosed herein are not to be interpreted as limiting, but merely as a basis for the claims and as a representative basis for teaching one of ordinary skill in the art to variously employ the disclosed subject matter in virtually any appropriately detailed structure and function. Further, the terms and phrases used herein are not intended to be limiting, but rather, to provide an understandable description. Additionally, unless otherwise specifically expressed or clearly understood from the context of use, a term as used herein describes the singular and/or the plural of that term.

The terms “a” or “an”, as used herein, are defined as one or more than one. The term “plurality”, as used herein, is defined as two or more than two. The term “another”, as used herein, is defined as at least a second or more. The terms “including” and “having,” as used herein, are defined as comprising i.e., open language. The term “coupled,” as used herein, is defined as “connected,” although not necessarily directly, and not necessarily mechanically.

It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment.

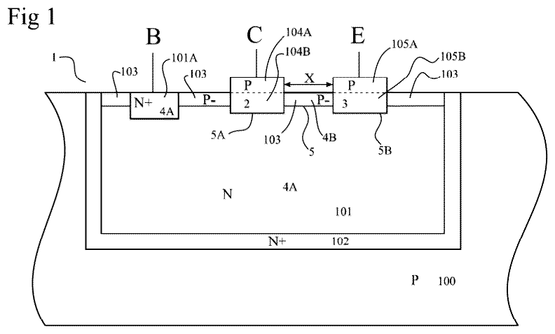

With reference to FIG. 1 there is shown a novel transistor device 1. The transistor device 1 was conceived as an improvement to bipolar junction transistor (BJT) devices and in certain aspects operates in a similar fashion. For this reason, the terminals of the device 1 are referred to using BJT nomenclature.

The device 1, which in this example is of a PNP type and is not shown to scale, is comprised from semiconductor material doped to provide a collector region 2, an emitter region 3 and a base region 4. The base region 4 lies between the collector region 2 and emitter region 3.

The collector region 2 and emitter region 3 are both of P type semiconductor, and as is conventional, the emitter region 3 may be more heavily doped than the collector region 2. For example, the net doping concentration of the collector region 2 may be greater or equal to 1×10¹⁸ cm⁻³, and the net doping concentration at the emitter region 3 may be greater or equal to 2×10¹⁸ cm⁻³. Alternatively, for ease of manufacture, they may instead have substantially the same net doping concentration. A collector terminal C is connected to the collector region 2, an emitter terminal E to the emitter region 3, and a base terminal B to the base region 4.

In contrast with a conventional BJT, the base region 4 of the transistor device 1 is comprised from two regions of different type semiconductor: a first region of N type material, herein after the N type base region 4A, and second region, hereafter referred to as the channel 4B, of P type material.

The base terminal B connects to the base region 4 through the N type region 4A. The N type base region 4A directly interfaces with the channel 4B to form a PN junction 5. The N type base region 4A directly interfaces with both the collector region 2 and emitter region 3.

The channel 4B extends between and directly interfaces with the collector region 2 and emitter region 3. The channel 4B has a very weak net doping concentration compared with that of the collector region 2 and emitter region 3. For example, the net doping concentration of the channel may be less or equal to 5×10¹⁶ cm⁻³.

Further, the channel 4B is formed to have a depth, i.e. dimension extending orthogonally from NP junction 5, which is significantly shallower than is conventional with junction field effect transistor (JFET).

The subregion is comprised from a first part and a second part. The net concentration of N dopant in the first part may be around 1e17/cm3. The net doping concentration in the second part may be, for example, about 1e18/cm3 or 1e19/cm3.

Below describes the semiconductor structure implementing the above mentioned features.

There is provided a P type substrate 100, which may be, for example, a silicon wafer or layer deposited by epitaxy on top of the wafer. Within the substrate 100 is provided an N type region 101. Separating the N type region 101 from the substrate 100 is an N+ region 102. Within the N type region 101 is provided a further N+ region 101A that extends to a surface of the substrate material. The N type region 101 and further N+ region 101A constitute the N type base region 4A of the transistor device 1, with the base contact B connected via the further N+ region 101A. The net concentration of N dopant in the N region 101 may be around 1e17/cm3. The net doping concentration of the N+ region 102 and further N+ region 101A may be, for example, about 1e18/cm3 or 1e19/cm3.

Extending across the top of the N region 101 is a lightly doped P-region 103 that provides channel 4B and interfaces with the N region 101 to provide the diode junction 5. The structure also includes two separated P regions 104, 105. A first part 104A, 105A of each P region 104, 105 is provided by respective separate portions of a P doped polysilicon layer. A second part 104B, 105B of each P region 104, 105 is formed in the silicon wafer and interfaces the N region 101 to provide respective diode junctions 5A 5B.

An example manufacturing process for the semiconductor structure is described. A first implant and diffusion process is used with a first mask to form the N+ region 102 in the P type substrate 100. Using a second mask, the N region 101 is formed by counter doping the N+ region 101 with P dopant whereupon the N region 101 extends to the surface of the wafer.

Preferably without using a mask, the surface of the wafer is further doped with P dopant to form the P− layer 103 across the surface of the wafer. The net doping concentration of the P− region 103 may, for example, be 5e16/cm3 or less. The depth of the P− region 103 is kept very small by ensuring little or no diffusion takes place. The relative thickness of the P-layer 103 compared with the other layers is exaggerated in FIG. 1 for intelligibility.

Using a third mask, N dopant is implanted through the wafer surface counter doping a portion of the P− region 103 to form the further N+ region 101A so that it is contiguous with the N region 101.

Using a forth mask, a layer of polysilicon material is deposited and etched to provide portions 104A 105A of the collector and emitter regions 2, 3. Using a fifth mask the polysilicon material is doped with P dopant and diffused downward to form second parts 104B 105B that interface with the N region 101.

Implantation of P dopant is followed by a short anneal, e.g. 10 seconds, to repair the crystal structure of the polysilicon and silicon wafer.

### Modes of Operation

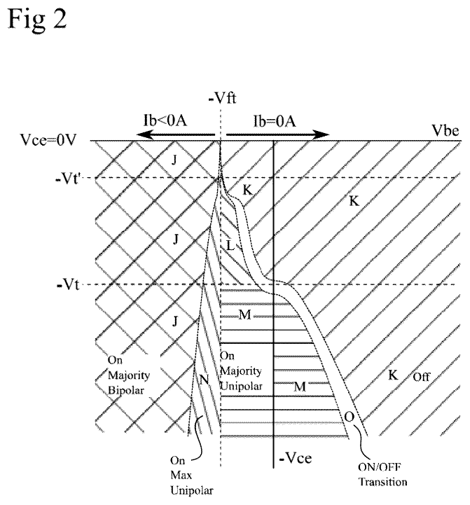

With reference to FIG. 2, the operating characteristics or modes of the device of FIG. 1 alter depending on the voltage across the collector terminal and emitter terminal (Vce) and the voltage across the base terminal and emitter terminal (Vbe).

With a PNP device, such as the one shown in FIG. 1, irrespective of the mode of operation, it is normally operated with a negative Vce, i.e. the voltage applied to the collector is more negative than the voltage applied to the emitter, and Vbe may be either positive or negative with a negative base-emitter junction forward threshold voltage Vft. Any current through the base terminal will be negative (in other words current is drawn out through the base terminal). In contrast, an NPN device is normally operated with a positive Vce, has a positive Vft, and any current through the base will be positive (in other words current is pushed into the device through the base).

Five modes of operation are shown labelled K, J, L M & N. When the device is OFF and there is no current through any terminal, the device is operating in region K. When the device is ON it may operate in one of modes J, L, M and N.

When the device is ON (i.e. there a current between the collector and emitter) and there is no or deminimis current through the base terminal (i.e. Ib=0A), excluding any temporary switching current due to capacitance effects, the device is operating in regions L or M. When the device is ON (i.e. there is a non-zero current between the collector and emitter) and there is current through the base terminal (i.e. Ib<0A), the device is operating in regions J or N.

### Operation With |Vce|<|Vt|

When the transistor device 1 operates with |Vce| smaller than |Vt|, the transistor device 1 functions as a normally OFF device. In other words, there is no current between the emitter 2 and collector 3 (the device is OFF (operating in (K) region)) when Vbe is zero.

If |Vbe| is increased such that the base-emitter diode junction 5B becomes forward biased (i.e. for a PNP transistor, Vbe becomes more negative than −Vft; for a NPN transistor, Vbe becomes more positive than Vft), then the device switches ON, operating in the ON Majority Bipolar region J, where current is drawn through the base terminal and the current between the collector and emitter is attributed in the majority to bipolar conduction.

Alternatively, if |Vbe| is increased in the opposite direction such that the base-emitter diode junction 5B becomes more reverse biased (i.e. for a PNP transistor, Vbe becomes more positive; for a NPN transistor, Vbe becomes more negative), then the device remains OFF (operating in region (K)).

Where |Vce| is greater than |Vt′| and less than |Vt|, the device operates in a similar manner as when |Vce| is less than |Vt′|, with the exception that as |Vbe| approaches but is less than |Vft|, the device enters the ON Majority Unipolar operating region L where the device is ON with zero current through the base terminal and the current between the collector and emitter is attributed in the majority to unipolar conduction.

As |Vbe| becomes greater than |Vft|, it enters a transition region N where the unipolar conduction current is at a maximum, and bipolar conduction current increases until bipolar conduction current is greater than unipolar conduction current whereupon the device operates in the ON majority bipolar conduction region J.

Advantageous a normally OFF device can be switched ON and operated in region L at a lower Vbe than existing BJTs, and, advantageously, lower than the base emitter diode junction forward voltage (Vft). When operating within L region the device has significantly higher current gain but lower magnitude of maximum collector current compared to operating within the region J for the same Vce. Because of the significantly lower Vbe the device when operating in the L region has a significantly higher current gain that existing BJTs—near infinite gain as there is substantially zero current through the base terminal.

### Operation With |Vce|>|Vt|

When the transistor device 1 is operated with |Vce| greater than a threshold voltage |Vt|, the transistor device 1 functions as a normally ON device. In other words, there is more than a de minimis current between the emitter and collector when Vbe is zero, e.g. because the base terminal is floating or tied to the emitter.

When |Vce| is greater than |Vt| and Vbe is at or around zero, the transistor operates in the ON majority unipolar operating region M where there is zero current through the base terminal and the current between the collector and emitter is attributed in the majority to unipolar conduction.

As |Vbe| increases above Vft, such that the base-emitter diode junction 5B becomes forward biased (i.e. for a PNP transistor, Vbe becomes more negative than −Vft; for a NPN transistor, Vbe becomes more positive than Vft), then the device operates in the transition region N where unipolar conduction is at a maximum and the bipolar conduction increases. As |Vbe| increases further, the proportion of Ice that can be attributed to bipolar conduction becomes greater than that attributed to unipolar conduction current whereupon operation is ON Majority Bipolar (region J).

The magnitude of Vbe needed to operate in the J region increases with increasing magnitude of Vce.

Alternatively, if |Vbe| is increased in the opposite direction such that the base-emitter diode junction 5B becomes more reverse biased (i.e. for a PNP transistor, Vbe becomes more positive; for a NPN transistor, Vbe becomes more negative), then the device will switch OFF (operate region K).

Between the OFF region K and the ON Majority Unipolar regions L and M is a transition region O where the operation of the device is unpredictable and/or difficult to control. For example, if the collector current in the OFF region K is less than 1 nA, and the collector current in the ON regions L and M is on the order of 1 uA or greater, then the collector current within the transition region O will be of the order of 10 nA to 100 nA.

The device 1 has a lateral spacing between the collector region 2 and emitter region 3 of distance X (see FIG. 1) which governs the length of the channel 4B. The values of Vt and Vt′ are correlated to the spacing X between the emitter and collector regions. As the value of X increases, the magnitude of |Vt| and |Vt′| increase. To enable the device to have good bipolar conduction characteristics when operating in the J region, the maximum value of X is typically 1.5 microns.

The nominal operating voltage range of a circuit governs the range of Vce values that will be applied to the transistors within it. With Vce known, the spacing X for each transistor device 1 within the circuit can be selected when designing the circuit to determine whether it operates as a normally ON or normally OFF device. For a typical logic circuit in which this device is typically expected to be employed, the nominal operating voltage range may be between 0V and |5V|.

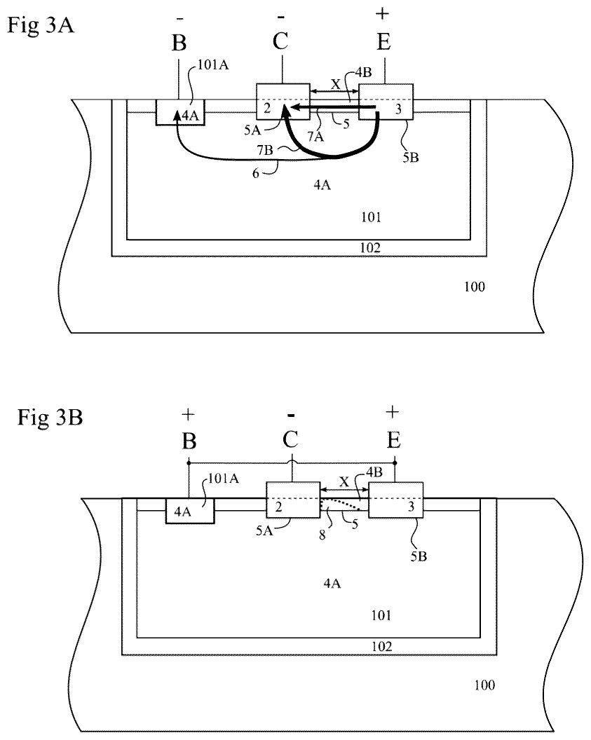

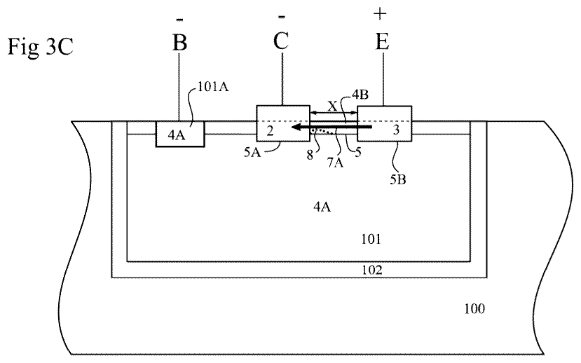

FIGS. 3A-3C illustrate the device of FIG. 1A with a lateral spacing X between the emitter and collector regions selected to be relatively large so that |Vce| is less than |Vt| and thus the device operates as a normally OFF transistor. In the present case the spacing X is such that Vce lies between Vt and Vt′ allowing the device to operate with the characteristics of any of regions J, K or L depending on Vbe.

FIG. 3A illustrates the normally OFF device operating in an ON majority bipolar condition (region J of FIG. 2). With the emitter terminal E at a relatively positive voltage compared with the base terminal B such that Vbe is more negative that Vft, the diode junction 5B between the emitter region 3 and sub-region 4A provided by N region 101 is forward biased allowing current flow (represented by arrow 6) through the diode junction 5B between the emitter terminal E and base terminal B. Consequently, there is a corresponding but much larger current between the emitter 3 and collector 2 attributed to both unipolar flow of charge carries through the channel 4B (represented by arrow 7A), and a yet larger current attributed to bipolar conduction via the N type base region 4A (represented by arrow 7B). The occurrence of unipolar conduction through the channel 4B provides the transistor with improved gain characteristics over transistors with conventional BJT structures.

Where the collector-emitter current is large, the bipolar current 7B may be significantly larger than the unipolar current 7A (e.g. on the order of 10× larger). This compares with a JFET where all (or close to all) of its current can be attributed to unipolar conduction through the channel.

FIG. 3B illustrates the device in an OFF condition represented by region K in FIG. 2. V_{CE} is identical to that shown in FIG. 3A but the base terminal B is floating or is tied to the emitter terminal E. As a consequence there is no current through the base terminal B.

This condition gives rise to a depletion region 8, shown notionally by the dotted line about the PN junction 5, which because the channel 4B is very shallow and weakly doped compared with the base sub-region, pinches offs the channel 4B increasing the channel's 4B resistance to an extent that there is substantially no current between the emitter 3 and collector 2.

FIG. 3C illustrates the device operating in an ON majority unipolar condition (region L of FIG. 2) through applying a non-zero voltage Vbe across the emitter and base that is less than Vft. As Vbe is less than Vft, the diode junction 5B between the emitter 3 and N type base region 4A is not sufficiently forward bias to permit current through and so there is no current through the base terminal B or base region 4A; however, because of the channel's 4B very low net doping levels, Vbe is sufficient to reduce the depletion region 8 around diode junction 5 to an extent that allow for current through unipolar conduction between the emitter region 3 and collector region 2 via the channel 4B (represented by arrow 7A). Operating within region L, the transistor has a high gain characteristic by virtue that Ib=0A. However, because of the shallowness of the channel, the maximum current that can be obtained before the channel saturates is comparatively low compared with operation in the J region.

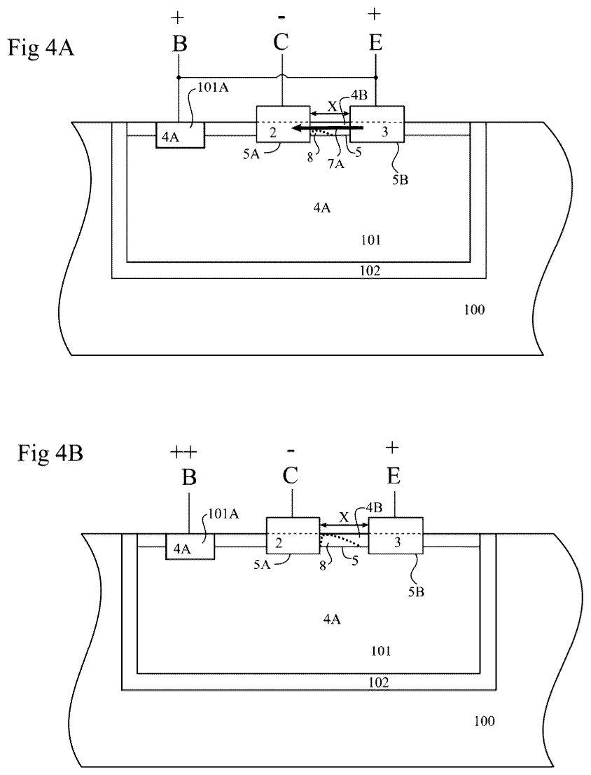

FIGS. 4A and 4B illustrate a variant device with an identical semiconductor structure to that of FIG. 1 except with a smaller spacing X between the collector region 2 and emitter region 3 and thus a shorter channel 4B. The spacing is selected such that when operated in a circuit that provides the same Vce range to the devices of FIGS. 3A-3C, Vce is greater that Vt and thus the device operates as a normally ON transistor.

It should be noted that although selecting the lateral spacing between the collector and emitter regions is the most convenient method to control the channel length, it may be possible to provide a longer channel length for a given lateral emitter-collector separation distance by forming the channel to have a circuitous path between the emitter and collector regions.

FIG. 4A illustrates the device in an ON majority unipolar condition. V_{CE} is identical to that described in relation to FIGS. 3A-3C but due to the closer spacing X between the collector 2 and emitter 3, and thus the shorter channel 4B, it is sufficient to overcome the intrinsic depletion region around diode junction 5 even in the condition that the base terminal B is floating or is tied to the emitter terminal E. As a consequence, although there is no current through the base terminal B, there is a current between the emitter and collector via the channel 4A.

FIG. 4B illustrates the device in an OFF condition. This is achieved by making the base terminal B significantly more positive than the emitter terminal E.

Note that the surface area of the transistor, i.e. the dimension into/out of the page with respective FIGS. 1, 3 and 4 can be selected to increase the width of the base region including channel 4B, depending on the maximum current rating that the transistor device 1 is required to meet.

The substrate layer 100 may be connected to a low voltage to ensure that the PN junction between the substrate and the N+ layer 102 is reverse biased. This inhibits unwanted effects from a parasitic lateral NPN BJT transistor formed between base regions of neighboring transistors.

The N+ later 102 is required in part to prevent the P implant 103 from creating a short circuit between the emitter and substrate, and to ensure that the parasitic vertical PNP BJT formed between the emitter and the substrate has very poor current conduction characteristics, favorably reducing the parasitic current by a factor of more than 100 compared to the collector current of the device.

### Alternative Embodiment with Variant Semiconductor Structure and Method of Manufacture

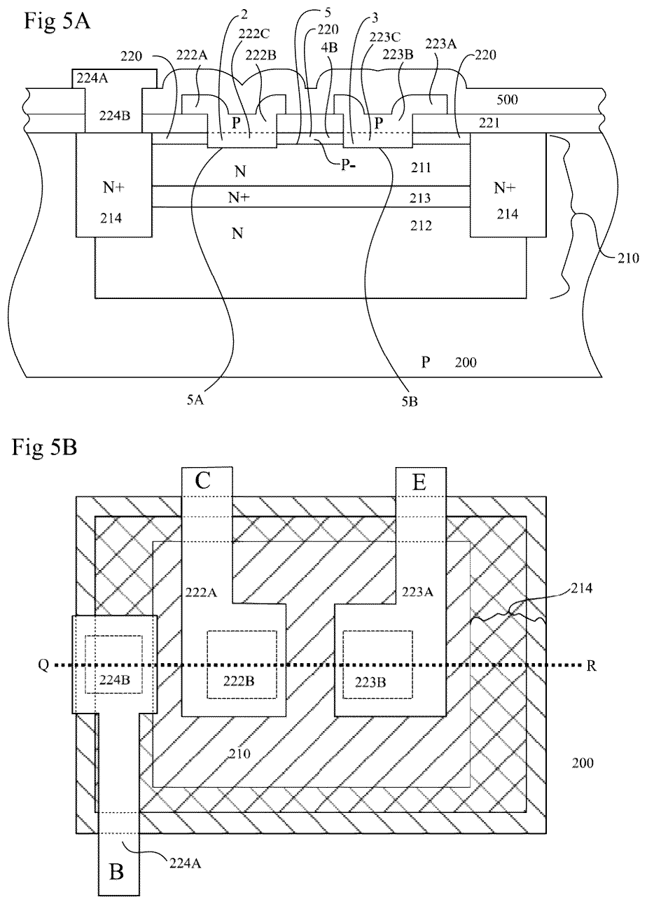

FIGS. 5A and 5B illustrate a variant semiconductor structure to implement the transistor device. The variant structure is advantageously easier to manufacture compared with that of FIG. 1. The dotted line QR represents the axis through which the section of FIG. 5A is taken.

There is provided a P type substrate 200, which may be, for example, a silicon wafer or layer deposited by epitaxy on top of the wafer. Within the substrate 200 is provided an N type well region 210 comprised from an upper N type region 211, a lower N type region 212 and an N+ type region 213 therebetween.

Surrounding the upper N type region 211 and N+ region 213 is a ring of a further N+ region 214. The N+ ring 214 overlaps with and extends outwards of the N Type well 210 to provide the N type region 4A of the transistor.

Lying above and in direct contact with the upper N type region 211 is a P− channel layer 220 that provides the channel 4B of the transistor. The P-channel layer lies in direct contact with the N type region 211 below it to provide diode junction 5.

Notably the N+ ring region 214 extends upwards, surrounding the P″ channel layer 220 to isolate the channels 4B from the substrate.

The doping concentration of the N type region 211 is in the range of 1e17/cm3 to 5e17/cm3. This is in comparison to the high doping levels (>1e19/cm3) usually found in the gate of a JFET.

The P− channel layer 220 has a net doping concentration in the order of 1e16/cm3 to 1e17/cm3.

Lying over the P-channel layer 220 is an oxide layer 221 The structure also includes two separated P regions 222, 223 each extending through the oxide layer 221 and P− channel layer 220 to provide the respective collector and emitter regions 2, 3.

A first part 222A, 223A of each P region 222, 223 is provided by portions of a P doped polysilicon layer lying on the oxide layer 221 to connect the emitter and collector terminals into the circuit. A second part 222B, 223B of each P region 222, 223 is provided by portions of the polysilicon layer extending through the oxide layer 221 to contact the surface of the wafer. A third part 222C, 223C of each P region 222, 223 is formed in the silicon wafer and interfaces the N region 211 to provide respective diode junctions 5A 5B.

A patterned oxide layer 500 and a metal layer 224 lie over the oxide and polysilicon layers 221, 223. The portions 224A of the metal layer are patterned to provides conductive tracts. A second part 224B of the metal layer 224 extends through an aperture within oxide layers 500 and 221 to contact the N+ region 214 to provide the base terminal.

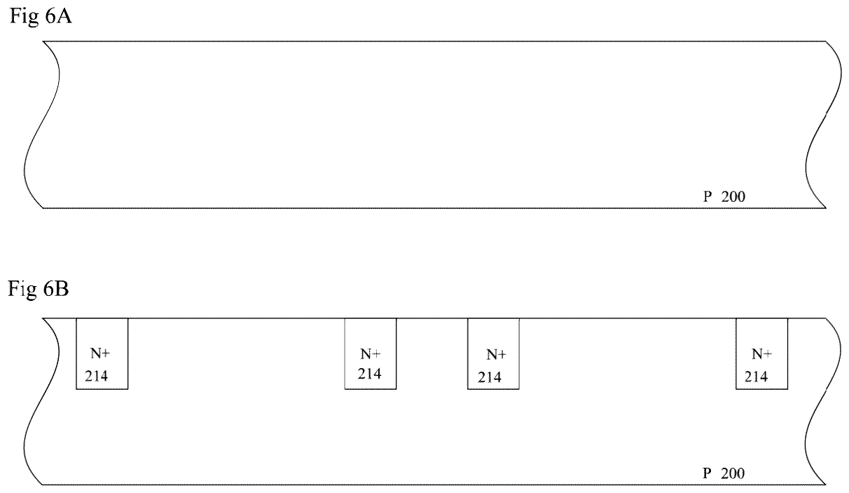

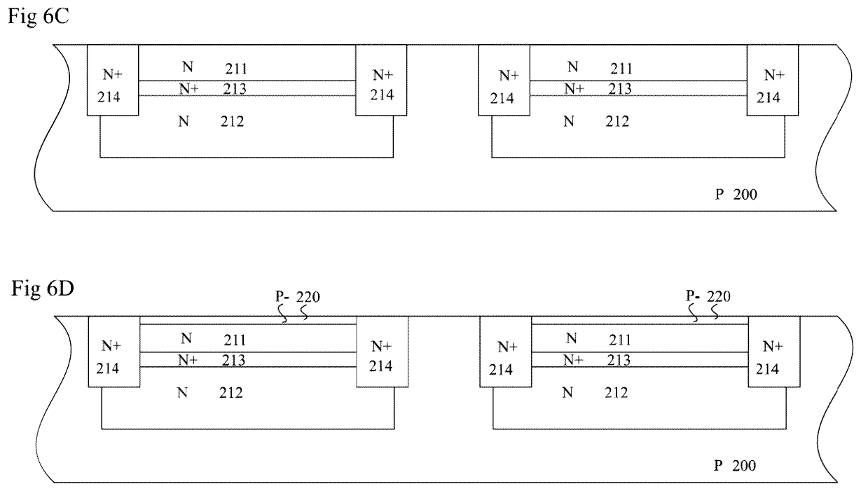

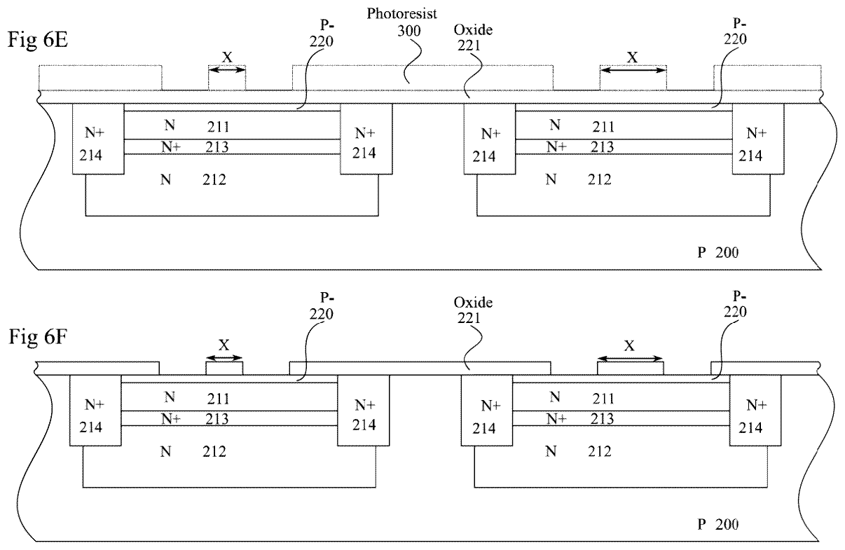

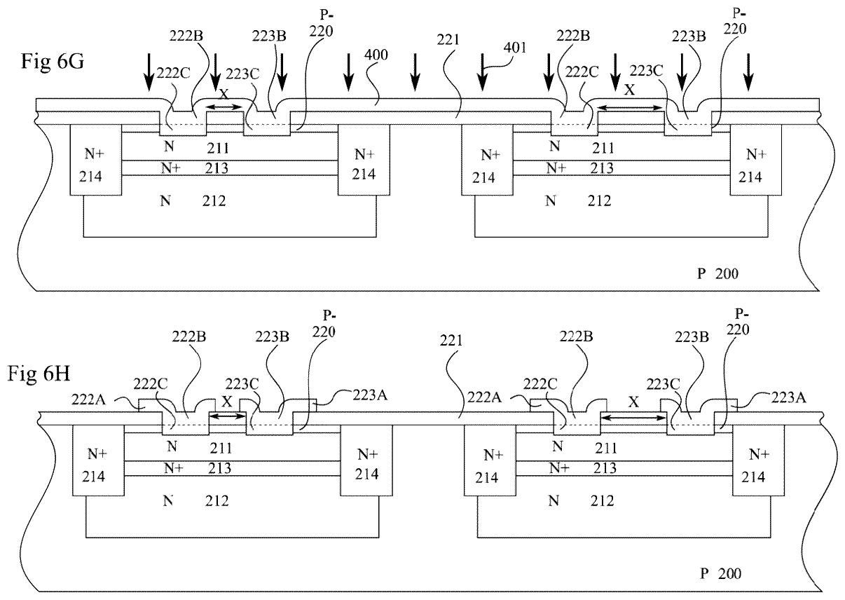

An example process for manufacturing two transistors with the structure of FIGS. 5A and 5B as part of an integrated circuit is illustrated with reference to FIGS. 6A-6I.

A first of the transistors is formed with a relatively small spacing X between the collector and emitter region and the other with a relatively large spacing, the spacing selected so that when in operation the first operates as a normally ON transistor and the other as a normally OFF transistor. The channel length of the second transistor may be selected such that it operates, when ON, with characteristics described in relation to either the L, N or J region of FIG. 2.

With reference FIG. 6A, a P type substrate 200 is provided. Turning to FIG. 6B, a mask, implant then diffusion process is used to form separate ring shaped (circular or otherwise) N+ regions 214, one for each transistor, in a P-type wafer 200.

With reference FIG. 6C, a mask and implant process is used to form the N type wells 210 within the respective rings 214. The diffusion process is omitted to leave the more highly doped N+ layer 213 beneath the surface, between N type layers 211, 212.

With reference FIG. 6D an unmasked P type implant process is used to form the P-channel layer 220. This may be carried out without a diffusion or anneal process. Because the doping required to form the P-channel region is so weak, the implant does not determinately affect the N+ regions.

With reference FIG. 6E, an oxide layer 221 is added to the wafer through a deposition process. Using a deposition process ensures the p-channel layer 220 is not harmed.

A photo resist 300 is applied over the oxide layer. The photo resist is patterned to define the spacing X between the collector and emitter regions and thus define the length of the channel 4B. The spacing X for the left hand transistor is, in this example, selected to be relatively small in order to provide a normally ON transistor, whereas the spacing X for the right hand transistor is selected to be relatively larger to provide a normally OFF transistor.

By way of example only for a 1 um fabrication process size, the right hand transistor may have a channel length between 1.2 microns and 1.5 microns. Whereas the left hand transistor may have a channel length equal to or less than 0.8 microns.

With reference FIG. 6F, the oxide layer is etched and the mask removed.

Referring to FIG. 6G, a layer of polysilicon 400 is deposited over (optionally the entire) wafer. The polysilicon layer 223 directly contacts the exposed surface of the P-layer 220 where the oxide layer 221 has been removed to form the collector and emitter contacts 222B, 223B.

A P type implant process 401 (represented by arrows) is carried out to convert the polysilicon to P type, the process also increases the net doping concentration of regions of the P-layer in direct contact with the polysilicon to form regions 222C, 223C of the collector and emitter terminals 2, 3. A short anneal step activates the implant without causing diffusion of the P− channel 220. Alternatively, in order to reduce the processing time a P-type polysilicon may be deposited.

Referring to FIG. 6H, the polysilicon layer 400 is masked and etched to pattern the collector and emitter terminals 2, 3 with tracks 222A 223A.

With reference to FIG. 6I, a further mask and etch process is used to expose a region of the N+ ring later 214 and metal 224 deposited to provide the base contact 224B, and etched with a pattern to provide routing layer 224A.

It will be appreciated that the device as variously described above could instead by implemented as a NPN device with an N-type channel, emitter and collector regions, and a P type base sub region. Where so the device will be operated with polarities reversed to that described above.

Rather than using a polysilicon layer, the emitter region and/or the collector region may be formed wholly within the wafer.

### Example Circuits Incorporating the Transistor Device

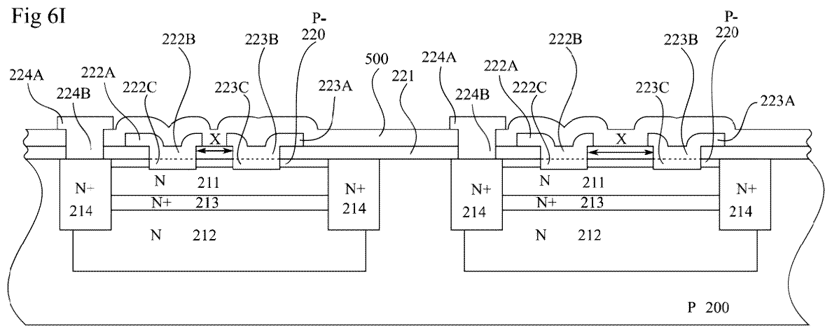

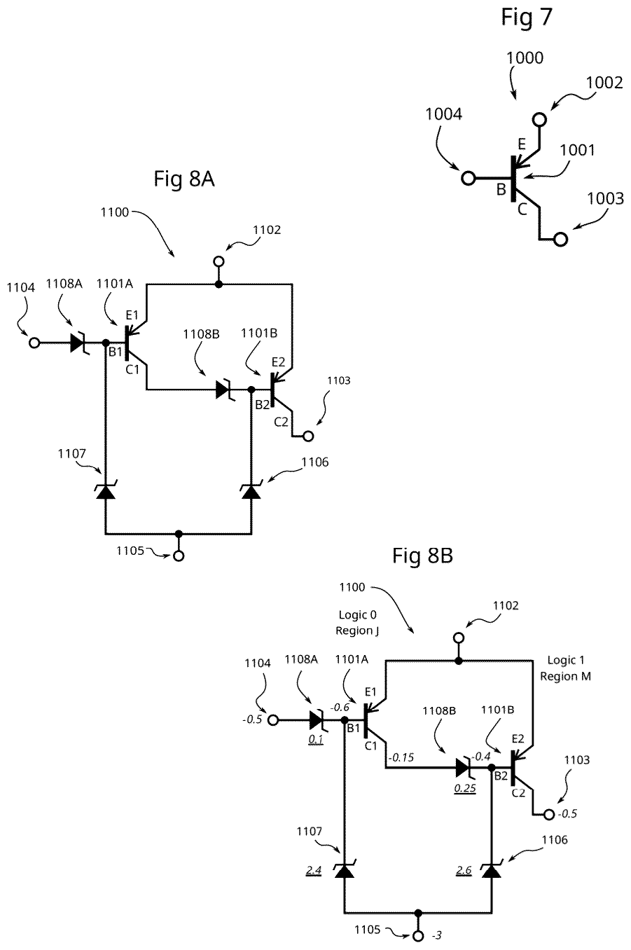

FIGS. 7-11 illustrate example circuits incorporating the afore described transistor device.

FIG. 7 illustrates a circuit fragment 1000 comprising a transistor 1001 that provides the function of an inverter logic gate. The transistor 1001 comprises a base terminal B, an emitter terminal E, and collector terminal C which acts as the output port of the transistor 1001.

The circuit 1000 fragment is adapted such that the transistor 1001 is switchable operable between a first ON state in which it operates in region M OR L of FIG. 2 where current through the collector terminal C is attributable exclusively to unipolar conduction between the collector and emitter terminals, and a second ON state operating in either the N or J region, where current through the collector terminal C is greater than in the first ON state and attributable to both unipolar and bipolar conduction between the emitter terminal E and collector terminal C; in the case of operation in the J region conduction is predominantly bipolar. In practice, it may be difficult to reliably operate in the L region and so switching between M, and N or J may be preferred.

The emitter terminal E is connected to a high (more positive) rail 1002. The collector terminal C is continuously connected to a load 1003, i.e. so as to be connected in both first and second states. The base terminal B is connected to a bi state signal source 1004 that switches between providing a high voltage signal and a low voltage signal at the base terminal B to vary Vbe between a first voltage Vbe1, e.g. −0.4V, and a second voltage Vbe2, e.g. −0.6V. Vbe1 is more positive than the forward bias voltage Vft of the base emitter junction of the transistor 1001. Vbe2 is more negative than Vft.

Because Vbe1 is more positive that Vft, when the signal source voltage signal is high, there is no current through the base terminal B. The resulting smaller current through the collector C provides a larger voltage drop, Vce1, across the emitter collector terminals. Conversely, because Vbe2 is greater (more negative) that Vft, when the signal source voltage signal is low, there is current through the base terminal B towards the signal source 1004. The larger current through the collector C results in a smaller voltage drop across the emitter collector terminals Vce2.

Operation in either the N or J region, where I_{ce} is attributable to bipolar conduction to some degree, results in clamping of Vbe2, minimising overshoot when switching from Vbe1. This increases the switching speed of the transistor 1001 between the two states. Additionally, it enforces Vbe2 as a known voltage limit which improves the reliability of circuit operation that comprises multiple of these transistors driving one another.

FIG. 8A illustrates a two stage buffer circuit 1100 incorporating, substantially identical, first and second transistors 1101A 1101B that each operate in the manner of transistor 1001 of FIG. 7. The output of the first transistor 1101A is arranged to drive the second transistor 1101B. The circuit 1100 examples how the continuous load maybe implemented, and how a desirable Vbe voltage swing can be effected. FIG. 8B illustrates the buffer circuit 1100 of FIG. 8A detailing example voltages through the circuit when operated between 0V and −3V high and low rails, and in the condition that the signal source 1104 provides a low voltage signal to the first transistor 1101A.

The emitter terminal E of each of the first and second transistors 1101A 1101B is connected to a high rail (or other high reference voltage). The base terminal B1 of the first transistor 1101A is connected to a two state voltage signal source 1104. The collector (output) C1 of the first transistor 110A is connected to the base terminal B2 of the second transistor 1101B, and the collector (output) C2 of the second transistor 1101B connected to an external load 1103.

The collector terminal C1 of the first transistor 1101A and the base terminal B1 of the second transistor 1101B are connected to a low reference voltage 1105 (hereafter referred to as the low rail) through a first diode 1106. The base B1 of the first transistor 1101A is connected to the low rail 1105 through a second diode 1107. The first transistor 1101A is connected to the bi-state signal source 1104 through a third diode 1108A. The collector C1 of the first transistor 1101A is connected to the base B2 of the second transistor 1101B through a further third diode 1108B.

Each of the first diode 1106, second diode 1107, third diode 1108A and further third diode 1108B are Zener diodes. In operation the first and second diodes 1106, 1007 operate in reverse bias. The third and further third diodes 1108A, 1108B operate in forward bias.

Referring to the first transistor 1101A, through the first diode 1106 the collector terminal C1 is constantly connected to the low rail 1105. The reverse biased second diode 1107 provides a pull down function at the base terminal B1. This relies on there being a leakage current through the second diode 1107. The electrical characteristics of the second diode 1107 are selected so that the voltage across the second diode 1107, during normal circuit operation, is below the breakdown voltage for the second diode 1107.

With reference also to FIG. 8B, the signal source 1104 is adapted switch between providing a high voltage signal of −0.15 volts and a low voltage signal of −0.5 volts, FIG. 8B shows the signal source 1104 whilst providing the low voltage signal.

With a low voltage signal, the voltage at the base terminal B1 is relatively low and so Vbe is relatively large. Because, in this example, the high rail is at zero volts, both the voltage at the base terminal B1 and Vbe2 are −0.6V. As Vbe2 is more negative than Vft for transistor 1101A, which may be, for example −0.55V, a current flows through the base terminal B1 out of the transistor 1101A and through the reverse biased second diode 1107 (by virtue of the leakage current) to the low rail 1105. The first transistor 1101A operates in predominately bipolar mode (J mode of FIG. 2). The ensuing relatively large current between the emitter and collector E1 C1 provides a relatively small voltage drop giving rise to a high voltage signal (−0.15V) (zero logic condition) at the base B2 of the second transistor 1101B. The presence of the first diode 1106 connects the collector C1 of the first transistor 1101A to the lower rail 1105 ensuring the first transistor is ON irrespective of the operating state of the second transistor 1101B.

Like the second diode 1107, the electrical characteristics of the first diode 1106 are selected so that the voltage across the first diode 1106, during normal circuit operation, is below the breakdown voltage for the first diode 1106. Again, current through the first diode 1106 is attributed to a leakage current.

As a consequence of the high voltage signal provided at the collector C1 of the first transistor, and a pull down function provided by the reversed bias first diode 1106, the voltage at the base B2 of the second transistor 1101B is relatively high (−0.4V) and thus Vbe is smaller than Vft for the second transistor 1101B (which is the same value as Vft of the first transistor 1101A). As a consequence, no current flows through the base B2 of the second transistor 1101B and so only a relatively small current passes through collector C2 of the second transistor 1101B, attributable exclusively to unipolar conduction (operating in M region of FIG. 2). This smaller current gives rise to a larger voltage drop across the emitter collector of the second transistor 1101B and thus a low voltage signal (−0.5V) at the output of the second transistor 1101B, that is of the same size as the low signal provided by the signal source 1104.

Current through the second diode 1107 derives from both the signal source 1104 and current from the base terminal B1, whereas current through the first diode derives solely from the collector C1 of the first transistor 1101A. Thus the current through the second diode 1107 is greater than the current through the first diode 1106. This leads to the smaller voltage drop across the second diode 1107 than across the first diode 1106.

When the signal source 1104 switches to provide a high voltage signal, −0.15V, the states of the first and second transistors 1101A 1101B swap over. The voltage at the base B1 of the first transistor 1101A rises to −0.4V; current through the base terminal B1 ceases and the first transistor 1101A switches to operation in N mode. The voltage at the collector C1 drops to −0.5V in turn causing the voltage at the base B2 of the second transistor 1101B to drop such that Vbe of the second transistor 1101B is greater than Vft and so a current is drawn through the base terminal B2 to the low rail 1105 through first diode 1106. The operation of the second transistor 1101B switches to the J region. The current through the collector C2 increases and so Vce drops providing a high voltage signal, −0.15V, at the collector C2. In this second state, current through the second diode 1107 derives from only the signal source 1104, whereas current through the first diode 1106 derives both from the collector C1 of the first transistor 1101A and base B2 of the second transistor 1101B. Thus the current through the second diode 1107 is less than the current through the first diode 1106. Consequently, there is a larger voltage drop across the second diode 1107 than across the first diode 1106.

Referring to the states illustrated in FIG. 8B, because there is no current through the base B2 of the second transistor 1101B, a larger current is drawn through the further third diode 1108B compared with the third diode 1108A. Consequently, the voltage drop (0.1V) across the further third diode 1108B is less than the voltage drop (0.25V) across the third diode 1108A. This swaps round when the signal source 1104 switches low. Advantageously, this has the effect of reducing the swing voltage at the bases B1 B2 of the transistor from between −0.15V and −0.5V-a 0.35V swing without the diodes 1108A 1108B, to between 0.4V and 0.6V, a 0.2V swing. The smaller voltage swing provides for increased switching speed of the first and second transistors 1101A 1101B.

The presence of the third diode 1108A and further third diode 1108B are preferred but either may be omitted with the consequence of a slower switching speed of the first and second transistors respectively.

Any one or more of the first 1106, second 1107, third 1108A and further third diodes 1108B may instead be implemented using a tunnel diode or a Schottky diode. For example, in one variant, the first 1106 and second 1107 diodes may be Zener diodes and the third 1108A and further third diodes 1108B Schottky diodes.

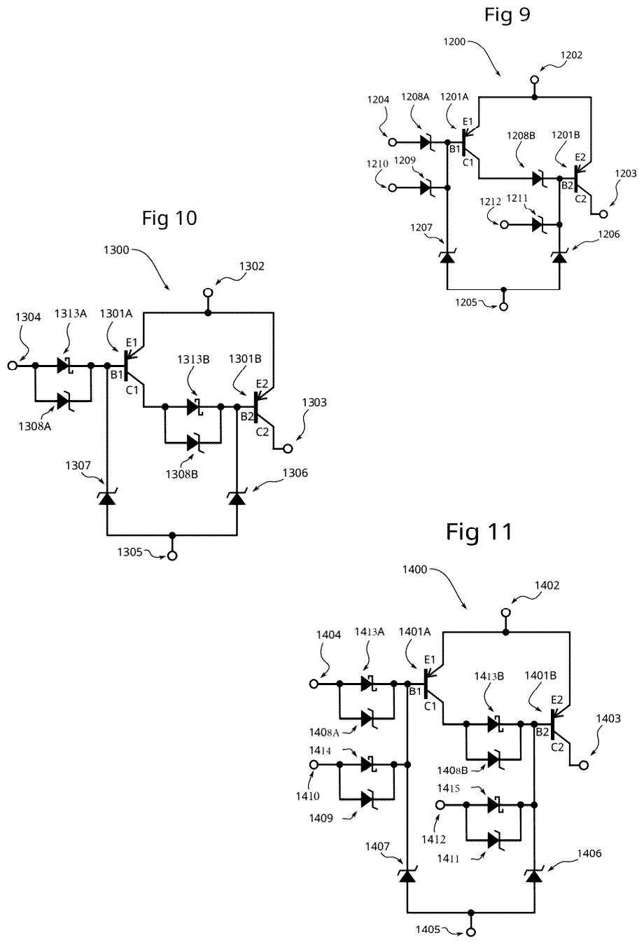

FIG. 9 illustrates a variant circuit 1200 that implements two NOR logic gates. The first stage NOR gate implemented using first transistor 1201A provides an input to the second stage NOR gate implemented using second transistor 1201B.

The purpose of FIG. 9 is to illustrate the simplicity in which the circuit of FIGS. 7 & 8 can be adapted to drive either or each transistor 1201A 1201B with multiple separate signal sources.

The circuit 1200 is based on that of FIG. 8 with the addition that the base B1 of first transistor 1201A is connected through a fourth diode 1209 to a second signal source 1210, and that the base B2 of the second transistor 1201B is connected through a further fourth diode 1211 to a third signal source 1212.

The second signal source 1210 and third signal source 1212 are each adapted to switchably provide a high or low voltage signal independently of each other and of the first signal source 1204. If either or both the first or second signal sources 1204 1210 provide a high signal, the voltage at the base terminal B1 will be high and so the first transistor 1201A will operate in the M region providing a low signal at its output. In the event one signal source 1204 1210 is providing a high signal and the other a low signal, diodes 1208A 1209 act to minimise crosstalk between the two signal sources 1204 1210 by virtue of one becoming reversed biased. If both provide a low signal, then the output of the first transistor 1201A will be high.

Similarly, if either or both the output of the first transistor 1201A and the third signal source 1212 provide a high signal, the voltage at the base terminal B2 of the second transistor 1201A will be high and so the second transistor 1201A will operate in the M region providing a low signal at its output. In the event one is providing a high signal and the other a low signal, diodes 1208B 1211 act to minimise crosstalk between the first transistor 1201A and third signal source 1212 by virtue of one becoming reversed biased. If both provide a low signal then the output of the second transistor 1201B will be high.

The advantage of this arrangement is that as many signal sources can be added as desired without adding further transistors into the circuit. This keeps the circuit size small.

FIG. 10 illustrates a further variant circuit fragment 1300 that provides faster switching and which can be formed as an integrated circuit in a smaller area than the circuit of FIG. 8A.

In addition to third Zener diode 1308A there is provided a fifth diode 1313A arranged in parallel with third Zener diode 1308A between the first signal source 1304 and the base B1 of the first transistor 1301A.

In addition to further third Zener diode 1308B there is provided a further fifth diode 1313B arranged in parallel with further third Zener diode 1308B between the collector C1 of the first transistor 1301A and the base B2 of the second transistor 1301B.

The Zener diode has a significantly greater capacitance than the Schottky diode for a given area as a result of its highly doped PN junction. This capacitance provides a shunt function during switching between high and low states of the signal source that more quickly effects the voltage change at the base terminal of the respective transistor. However, on its own the Zener diode has to be relatively large to allow sufficient current through it to provide the voltage drop across it that is desired; up to 0.25V in the example of FIG. 8B. This leads to a capacitance that is too great causing the base voltage to overshoot during switching which limits the maximum switching frequency.

In contrast, the Schottky diode has a relatively low capacitance but can pass a significantly larger current than a Zener of comparable size. Arranged in parallel the advantageous characteristics of both can be used; during the static state between switching, most of the current can pass through the Schottky diode, whilst the higher capacitance of the Zener provides fast switching.

Advantageously, the shunt function of the Zener can be provided with a much smaller diode size than needed when used to provide the required voltage drop as well. In testing by the inventors, a total space required for the Schottky and Zener diode together was around five times smaller than the required size of Zener diode if used alone. Because the capacitance of the Zener is reduced, but still greater than the Schottky alone, the maximum switching frequency is increased. In a variant, the Zener diode may be replaced with a tunnel diode.

FIG. 11 illustrates a further variant circuit fragment 1400 which combines the features first described in FIGS. 9 and 10, namely between each respective signal source 1404, 1410, 1212 and the respective base terminals B1 B2 of the first and second transistors 1401A 1401B are provided a pair of Schottky and Zener diodes 1408A 1413A; 1409.1414; 1408B, 1413B; 1411, 1415.

It will be appreciated that the circuits of FIGS. 7-11 may be implemented instead with NPN transistors instead of PNP transistors, making the necessary changes to account for the polarity reversal.

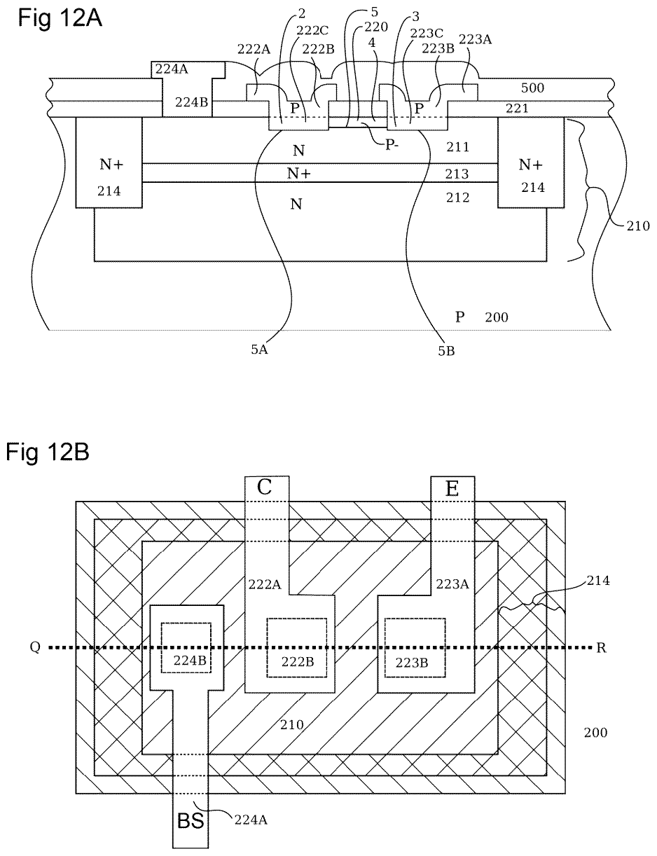

FIGS. 12A and 12B illustrate another variant layer structure in which the metal base contact 224 directly contacts to the N well region 210 to provide a Schottky diode junction between the metal base contact 224B and the N region 211. The metal 224 also provides a terminal BS to the base of the transistor through the Schottky diode. This structure can be used, for example, to provide the combination of the first transistor 1101A and third diode 1108A, and the second transistor 1101B and further third transistor 1108B of a variant of the circuit 1100 of FIG. 8 that employs a Schottky diode for the third 1108A/further third diode 1108B.

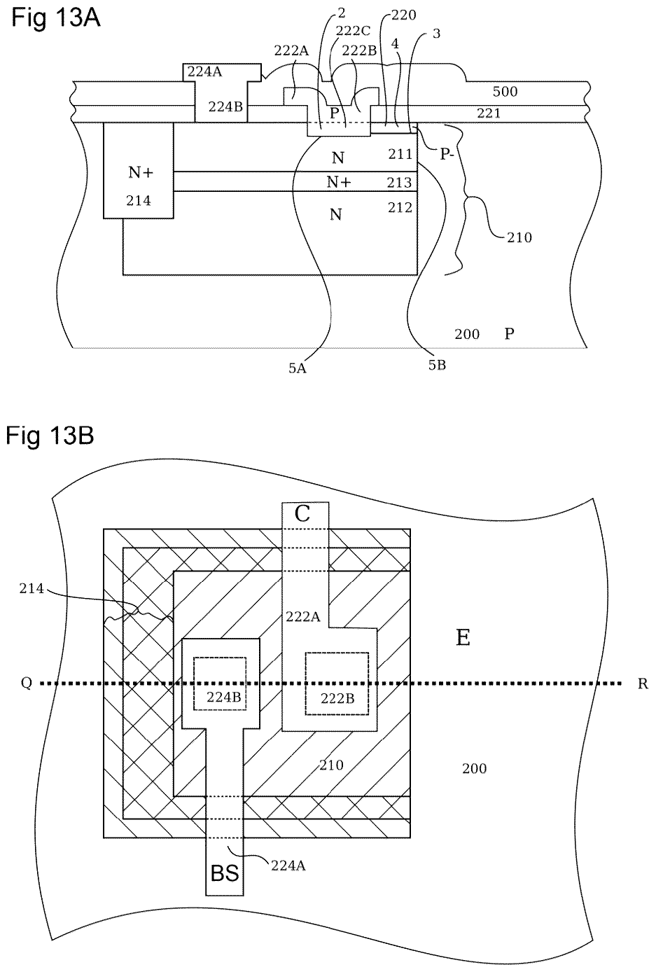

FIGS. 13A and 13B illustrate a variant layer structure that provides improvements over that described in FIG. 5. The N+ ring 214 is instead formed as ‘C’ shape (or may be excluded entirely from the structure) resulting in the P-channel 220 directly contacting the P Substrate 200. In addition, one of the P polysilicon regions 222 223 may be excluded (FIGS. 13A & 13B shows the variant with layer 223 excluded). With this structure the substrate 200 may be used as either the collector or emitter (in this example the emitter), and this may be common between multiple transistors. This arrangement allows for smaller size transistors with reduced base capacitance (and thus increased speed) as well as allowing for simplified circuit design.

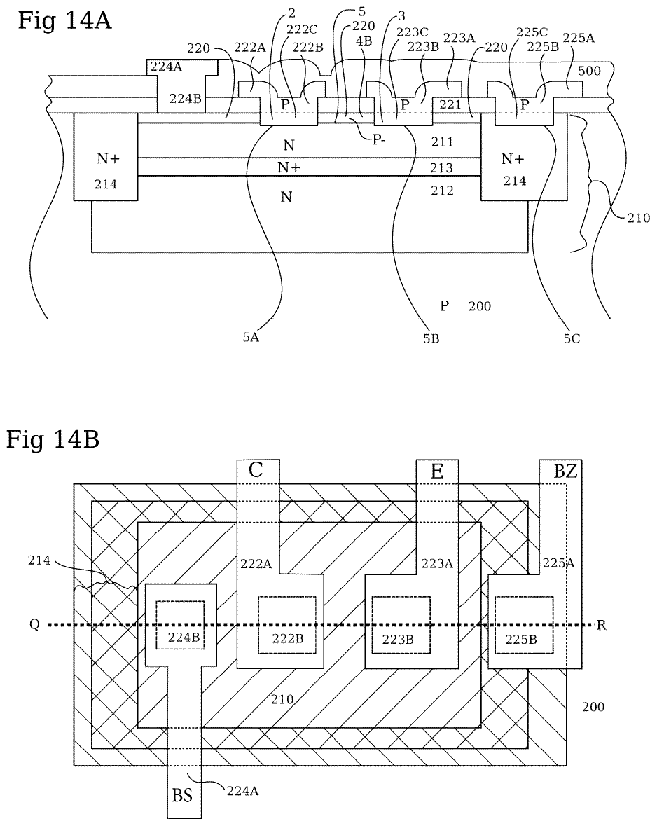

FIGS. 14A and 14B illustrate an alternative structure that comprises an additional P polysilicon region 225 within and in direct contact with the N+ region 214. The additional P polysilicon region 225 may be formed in the same processing step used to form the collector and emitter regions 222 223. The additional polysilicon region 225 and N+ region 214 provides a diode junction 5C, that may, depending on the doping of the N+ region function as a Zener diode junction or a Tunnel diode junction. The additional polysilicon region 225 is also used to provide an additional terminal BZ to the base of the transistor through the Zener or tunnel diode. When the transistor is implemented to provide the first transistor 1101A of FIG. 8, the diode junction 5C may be operated in reverse bias to provide the second pull down diode 1107, similarly it can be used to provide the combination of the second transistor 1101B and first diode 1106. With both contacts BS BZ, the structure cane be used to implement the combination of transistor 1301A and third and fifth diodes 1308A, 1313A.

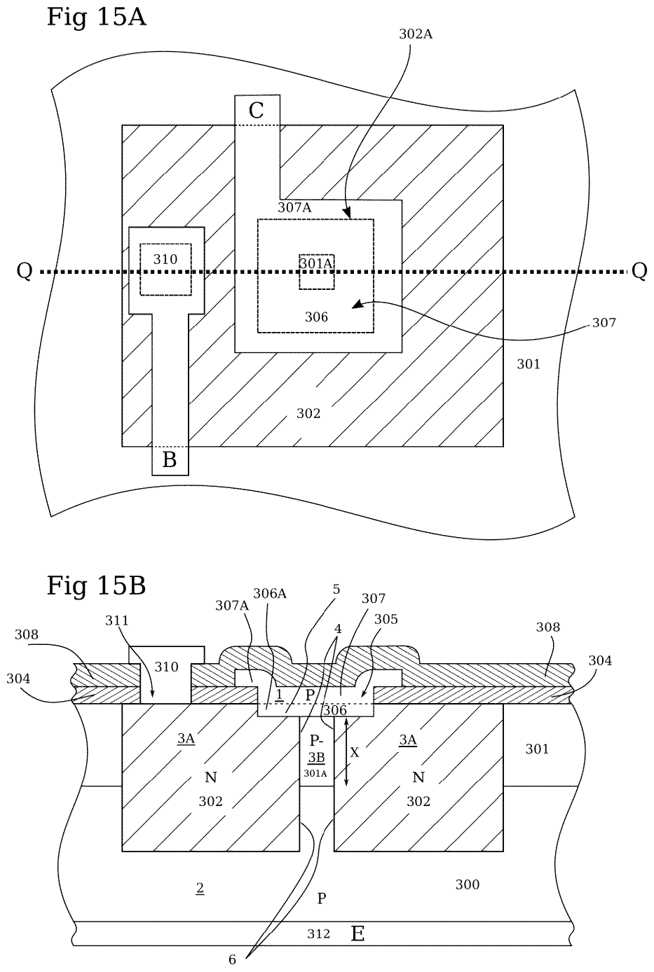

FIGS. 15A & 15B illustrate a semiconductor layer structure to implement a vertical equivalent of the transistor of FIG. 1 that can be incorporated in any of the circuits of FIGS. 7-11.

The device, which in this example is of a PNP type and is not shown to scale, is comprised from silicon semiconductor material doped to provide a collector region 1, an emitter region 2 and a base region 3. The base region 3 lies between the collector region 1 and emitter region 2.

The collector region 1 and emitter region 2 are both of P type semiconductor, and as is conventional, the emitter region 2 may be more heavily doped than the collector region 1. For example, the net doping concentration of the collector region 1 may be greater or equal to 1×10¹⁸ cm⁻³, and the net doping concentration at the emitter region 2 may be greater or equal to 2×10¹⁸ cm⁻³. Alternatively, they may instead have substantially the same net doping concentration. A collector terminal C (see FIG. 15A) is connected to the collector region 1, an emitter terminal E to the emitter region 2, and a base terminal B to the base region 3.

The base region 3 of the transistor device is comprised from two regions of different type semiconductor: a first region of N type material, herein after the N type base region 3A, and second region, hereafter referred to as the channel 3B, of P type material.

The base terminal B connects to the base region 3 through the N type region 3A. The N type base region 3A directly interfaces with the channel 3B to form a PN junction 4. The N type base region 3A also directly interfaces with both the collector region 1 and emitter region 2 to provide respective PN junctions 5 and 6.

The channel 3B extends between and directly interfaces with both the collector region 1 and emitter region 2. The channel 3B has a very weak net doping concentration compared with that of the collector region 1 and emitter region 2. For example, the net doping concentration of the channel 3B may be less or equal to 5×10¹⁶ cm⁻³.

Further, the channel 3B has a lateral width, i.e. dimension extending orthogonally from NP junction 4 with the N type base region 3A, which is significantly smaller than is conventional for a junction field effect transistor (JFET). In one embodiment the lateral width may be 0.2 microns

The net concentration of N dopant in the N type base region 3A may be around 1e17/cm3.

The separation between the collector and emitter regions, which equates to the length of the channel 3B, may be less or equal to 1.5 microns, favourably equal or less than 0.8 microns. In one embodiment it is around 0.3 microns.

Below describes a semiconductor structure implementing the above mentioned features.

Provided on a P type substrate 300, which provides the emitter region 1, is a comparatively lowly doped P− layer 301 having a net doping concentration less or equal to 5×10¹⁶ cm⁻³.

A square annular N type region 302 providing the base sub-region 3A, extends entirely through the P− layer 301 and partially into the substrate 300. The N type region 302 defines a centrally located aperture that extends entirely through the N type region 302 between the top and bottom sides of the P-layer to define a portion 301A of the P-layer 301 providing the channel 3B that is isolated from the remainder of the P− layer 301.

The N type region 302 could take forms other than square annulus, e.g. annulus, rectangular annulus or an irregular annulus. The aperture does not need to lie directly in the center of the N type region 302 but preferably lies entirely within the perimeter 302A of the N− type region 302 to ensure the channel 3B is isolated from the remainder of the P− layer 301.

As illustrated in FIG. 1A, typically, the P-type layer 301 will extend laterally around all sides of the N type region 302.

A first oxide layer 304 lies on top of the P-layer 101A. Formed through the first oxide layer 304 is a first window 305. A P type region 106, provided in part by a polysilicon layer 307 formed through first window 305 on the P-layer 301 and part by a converted portion 306A of the epitaxial layer 301, lies directly over and in contact with portion 301A, and the N type region 302 to define interface 5. A portion 307A of the polysilicon layer extends over the first oxide layer 304 providing a conductive track to interconnect the transistor into a circuit.

A second oxide layer 308 is provided over the first oxide layer 304 and polysilicon layer 307 to isolate the polysilicon layer 307 from a patterned metal layer 310. A further window 311 through the first and second oxide layers 304, 308, allows the metal layer 310 to directly contact the N type region 302 to provide the base contact B. In this example the junction between the metal layer 310 and N type region 302 provides a Schottky diode.

A further metal layer 312 is provided on an opposite facing side of the substrate 300 to that on which P-layer 301 lies to provide an emitter contact E. Although not shown in the FIG. 15B, a portion of the substrate 300 lying immediately adjacent the metal layer 312 is more heavily doped to provide good omic contact.

An example fabrication process is described. The P− layer 301 is grown using epitaxy onto the P type substrate 300. The thickness X of the epitaxy layer is selected to define the desired channel length and thus separation between the collector and emitter regions.

Subsequently, a first implant and diffusion process is used with a mask defining a square annular pattern to convert a region of the P-layer 301 and a portion of the substrate 300 directly beneath it to form the square annulus N-type region 302 and define the channel 3B and diode junctions 4 and 6.

The first oxide layer 304 is deposited on the surface of the p-layer 301. A first mask and etch process is used to form first window 305. A pattern of polysilicon is then deposited over the window 305 and the first oxide layer 304 to provide polysilicon layer 307. Using a second mask, the polysilicon material is doped with P dopant and diffused downward to form portion 306A and the collector-base diode junction 5 within the epitaxial layer 301. Implantation of P dopant is followed by a short anneal, e.g. 10 seconds, to repair the crystal structure of the polysilicon and silicon wafer.

The second oxide layer 308 is deposited over the first oxide layer 304 and the polysilicon layer including P type region 306. A second mask and etch process is used to form a further window 311 through the first and second oxide layers 304 308. The metal layer 310 is deposited over the second oxide layer 308 including though the further window 311 to form the Schottky diode junction with the base region 302, and conductive tracks over the second oxide layer 108 to interconnect the base into a circuit.

Additionally, the backside of the substrate is metallized to form layer 312 providing the emitter terminal E.

In the example circuits of FIGS. 8 and 9, the Zener diodes 1108, 1109, 1208, 1209, 1211 may be substituted for Schottky diodes. Using Schottky diodes instead may allow for a smaller base size and easier routing compared with using Zener diodes.

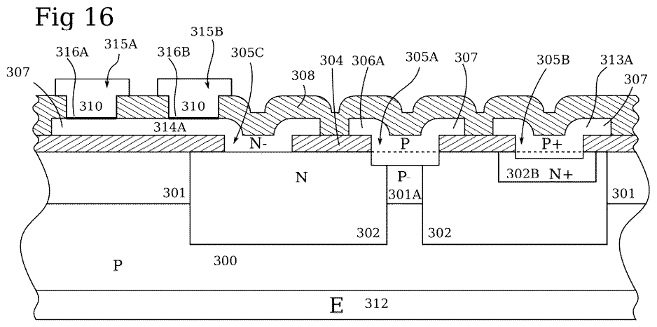

FIG. 16 illustrates the semiconductor layer structure of FIG. 15 adapted to provide connection of two Schottky diode connections to the base and one Zener diode connection to the base as might be used, for example, to implement a variant of the circuit of FIG. 9 in which diodes 1208A 1209 are implemented by Schottky diodes.

Defined through the first oxide layer 304, directly above the base 3 are a first window 105A, a second window 105B and a third window 105C. The first window 305 lies directly over portion 301A of the epitaxial layer, the second window 305B lies directly over a N+ region 302B of the base 3 form in or adjacent to the N region 302. The third window 305C lies directly over the N region 302.

A P type region 306, provided in part by a portion of polysilicon layer 307 formed through first window 305A on the P-layer 301 and part by a converted portion 306A of the epitaxial layer 301, lies directly over and in contact with portion 301A, and the N type region 302 to define interface 5. A portion 307A of the polysilicon layer extends over the first oxide layer 304 providing a conductive track to interconnect the collector terminal into a circuit.

A second portion of the polysilicon layer 307 provides a P+ region 313 extending through the second window 305B so as to be in direct contact with the N+ region 302B to provide a Zener diode junction with the base 3. A portion 313A of the P+ region also extends over the first oxide layer 304 for the purpose of connecting the Zener diode into a circuit.

A lightly doped N− layer is provided through the third window 305C so as to be in direct contact with N type region 302. The N− layer extends over the first oxide layer.

A second oxide layer 308 is provided over the first oxide layer 304 and polysilicon layer 307. Formed through second oxide layer 308 are windows 315A, 315B. A patterned metal layer 310 is formed over the second oxide layer 308 and through windows 315A, 315B to form two Schottky diode junctions 316A, 316B connected to the base region 3 of the transistor.

A further metal layer 312 is provided on an opposite facing side of the substrate 100 to that on which P-layer 301 is provided to provide an ohmic contact for the emitter contact E.

An example fabrication process is described. The same steps described above are used to form square annulus N-type region 302, define the channel 3B and diode junctions 4 and 6. An additional mask and implant process is used to form N+ region 302B.

The first oxide layer 304 is deposited on the surface of the p-layer 301. A first mask and etch process is used to form windows 305A, 305B and 305C through the oxide layer 304. Using a further mask and etch process, a pattern of polysilicon is deposited over the first oxide layer including the windows 305A, 305B, 305C to provide polysilicon layer 307.

Using a second mask, a first portion of the polysilicon layer 307 lying over window 305A is doped with P dopant and diffused downward to form region 306 including portion 306A and the collector-base diode junction 5 within the epitaxial layer 301.

Using a third mask, a second portion of the polysilicon layer lying over window 305C is doped with P dopant and diffused downward to form P+ region 313 and the Zener diode base junction within the epitaxial layer 301.

Implantation of P dopant is followed by a short anneal, e.g. 10 seconds, to repair the crystal structure of the polysilicon and silicon wafer.

Using a fourth mask, a third portion of the polysilicon layer 307 lying over window 105B is lightly doped with N dopant to provide an N− layer.

The second oxide layer 308 is deposited over the first oxide layer 304. A second mask and etch process is used to form the windows 315A 315B through the second oxide layer 308. A patterned metal layer 110 is formed over the second oxide layer 308 and though window 315A 315B to form the Schottky junctions connected with the base region 302 as well as the conductive tracks over the second oxide layer 308.

Additionally, the backside of the substrate is metallized to form layer 312 providing the emitter terminal E.

The subregion 3B may not extend entirely through the epitaxial layer 101. This may be necessary if the epitaxial layer 101 is thicker than spacing desired between the emitter and collector. Although this may reduce the performance of the transistor, it may be acceptable where a very small base width is desired.

The terminal for the emitter region may instead be provided on the same side of the substrate as the base and collector terminals. This may require forming a P+ region extending through the epitaxial layer. The substrate may instead be used to provide the collector region and the emitter region provided by P region 306.

The Abstract is provided with the understanding that it is not intended be used to interpret or limit the scope or meaning of the claims. In addition, in the foregoing Detailed Description, various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

The corresponding structures, materials, acts, and equivalents of all means or step plus function elements in the claims below are intended to include any structure, material, or act for performing the function in combination with other claimed elements as specifically claimed. The description herein has been presented for purposes of illustration and description, but is not intended to be exhaustive or limited to the examples in the form disclosed. Many modifications and variations will be apparent to those of ordinary skill in the art without departing from the scope of the examples presented or claimed. The disclosed embodiments were chosen and described in order to explain the principles of the embodiments and the practical application, and to enable others of ordinary skill in the art to understand the various embodiments with various modifications as are suited to the particular use contemplated. It is intended that the appended claims below cover any and all such applications, modifications, and variations within the scope of the embodiments.

Although specific embodiments of the subject matter have been disclosed, those having ordinary skill in the art will understand that changes can be made to the specific embodiments without departing from the scope of the disclosed subject matter. The scope of the disclosure is not to be restricted, therefore, to the specific embodiments, and it is intended that the appended claims cover any and all such applications, modifications, and embodiments within the scope of the present disclosure.

What is claimed is:

1-24. (canceled)

25. A circuit comprising:
a first transistor,
a base of the first transistor connected to a source of a two state logic signal;
the first transistor having:
a collector region provided by a first region of semiconductor of a first type, and a collector terminal associated with the collector region;
an emitter region provided by a second region of semiconductor of the first type; an emitter terminal associated with the emitter region;
a base region provided by a third region of semiconductor lying between and interfacing with both the collector region and emitter region; a base terminal associated with the base region;
wherein the base region includes:
a sub-region of semiconductor of a second type; and
a channel of semiconductor of the first type;
wherein the base terminal contacts the base region;
the sub-region interfaces with the channel to provide a first diode junction, and interfaces with both the emitter region and the collector region to form further diode junctions,
and the channel interfaces with and interconnects the collector region and the emitter region, the channel extending away from the first diode junction; and
in which the circuit is adapted to switchably operate, in response to a change in the two state logic signal between a first state and a second state;
a load is connected to an output of the first transistor, and a voltage V_{ce} across the collector and emitter to allow for a non-zero current through the collector terminal in both the first and second states; and
in the first state a first voltage V_{be1} is applied across the emitter and base of the first transistor to cause a first non-zero current I_{ce1} between the collector and emitter of the first transistor; and in the second state a second voltage V_{be2} of a same polarity to V_{be1} is applied across the emitter and base of the first transistor to cause a second, larger, non-zero current I_{ce2} between the collector and emitter of the first transistor, and
wherein |V_{ce|} is above a |threshold voltage|, and V_{be1} V_{be2} are selected so that in the first state I_{ce1} is predominantly attributable to unipolar conduction, and in the second state I_{ce2} is attributable to both unipolar and bipolar conduction.

26. A circuit according to claim 25 comprising a first diode connected between the output of the first transistor and a reference voltage that provides, at least in part, the load.

27. A circuit according to claim 25 comprising a second diode connected between the base of the first transistor and a reference voltage.

28. A circuit according to claim 25 comprising a third diode, and in which the source of the two state logic signal is connected to the base of the first transistor through the third diode.

29. A circuit according to claim 28 wherein the third diode is comprised from a semiconductor region that provides the base of the first transistor.

30. A circuit according to claim 28 in which the third diode is a Schottky diode.

31. A circuit according to claim 28 wherein the third diode is a Zener or tunnel diode and is comprised from a further semiconductor region in direct contact with a semiconductor region that provides the base of the first transistor.

32. A circuit according to claim 28 wherein the first diode and/or a second diode connected between the base of the first transistor and a reference voltage are, when the circuit is operating, reversed biased, and in which the voltage across the first diode and/or the second diode is selected to be below a breakdown voltage of the respective diode.

33. A circuit according to claim 28 comprising a further two state logic signal source, and a fourth diode, the further two state logic signal source connected to the base of the first transistor through the fourth diode.

34. A circuit according to claim 28 comprising a fifth diode, the fifth diode arranged in parallel to the third diode between the source of a two state logic signal and the base of the first transistor; and wherein one of the third and fifth diodes is a Schottky diode and the other diode is a Zener or a tunnel diode.

35. A circuit according to claim 25 wherein the channel has a dimension extending from the first diode junction of less than or equal to 0.25 micron.

36. A circuit according to claim 25 wherein the sub-region of the base region comprises a first portion and a second portion, and wherein:
the first portion has a higher net doping concentration than the second portion;
the base terminal electrically connects to the second portion through the first portion; and
in which the second portion interfaces with the channel to provide the first diode junction, and interfaces with both the emitter region and the collector region to form the further diode junctions.

37. A circuit according to claim 36 wherein a net doping concentration of the channel is less than or equal to one times the net doping concentration of the second portion of the sub-region.

38. A circuit according to claim 37 wherein the second portion of the sub-region of the base has a net doping concentration of between 5e16/cm3 to 5e17/cm3.

39. A circuit according to claim 38 wherein the first portion of the sub-region of the base has a net doping concentration greater than or equal to 1e18/cm3.

40. A circuit according to claim 36 wherein the sub-region is provided in a semiconductor substrate layer of the first type, and the circuit further comprises a highly doped region of the second type of semiconductor that lies between and separates the second portion of the sub-region from the semiconductor substrate; and the highly doped region having a high net doping concentration compared with the sub-region.

41. A circuit according to claim 36 wherein the emitter region and/or the collector region are provided by a doped polysilicon layer provided on a silicon die that defines the base region.

42. A circuit according to claim 36 wherein the sub-region encircles the channel such that the interface between the sub-region and channel extends continuously around the channel.

43. A method of operating the first transistor of the circuit of claim 25:
wherein when the first transistor is ON |Vce|<|Vft|, and |Vbe|<=|Vce|,
where Vce is the voltage across the collector and emitter terminals,
Vft is a forward bias voltage of a base region and emitter region diode junction; and
Vbe is a voltage across the base and emitter terminals.

44. A method according to claim 43 wherein |Vce|≤½×|Vft|.
